(19) United States
(12) Patent Application Publication
(10) Pub. No.: US 2012/0026695 A1
(43) Pub. Date: Feb. 2, 2012

(54) Compartmentalized Pump Termination Enclosure for Multiple Pumps with Integral Load Disconnects

(76) Inventor: Bruce William Grindeland, Franklin, WI (US)

(21) Appl. No.: 13/190,409

(22) Filed: Jul. 25, 2011

Related U.S. Application Data
(60) Provisional application No. 61/368,213, filed on Jul. 27, 2010.
(60) Provisional application No. 61/367,923, filed on Jul. 27, 2010.

(51) Int. Cl. H05K 7/00

(52) U.S. Cl. 361/724

(57) ABSTRACT

A Compartmentalized Pump Termination Enclosure for Multiple Pumps with Integral Load Disconnects assembly consisting of multiple compartments arranged so as to allow service of each individual load side compartment without exposure to line voltages while still maintaining operation of the other pumps within the pumping system. The assembly includes a plurality of load side disconnect compartments each including a lockable handle operator that that is interlocked with its corresponding load side compartment door. The handle operators are mechanically connected to the disconnecting devices via flexible cables or mechanical linkage. A key feature/distinction of this invention is that the disconnecting devices have their line and load side compartments segregated, so that when the handle operator is switched to the OFF position there are no components (e.g. disconnecting device and/or its conductors) within the load side compartment that remain energized by line voltage. The handle operator, when OFF, grants access to the load side compartment only.

### CROSS-REFERENCE TO RELATED APPLICATIONS

This system/assembly I have described can be used in the way I described a previous provisional patent(s) which I, Bruce William Grindeland, have filed (Application No: 61/368,213, Filing or 371(c) Date Jul. 27, 2010). This system/assembly also utilizes some concepts similar to those of (a) non-provisional patent(s) application(s) I have filed (Application No: 61367923 EFS ID: 8095378 & Application No: 13190337 EFS ID: 10593378).

### STATEMENT REGARDING FEDERALLY SPONSORED RESEARCH OR DEVELOPMENT

Not Applicable

### REFERENCE TO SEQUENCE LISTING, A TABLE, OR A COMPUTER PROGRAM LISTING COMPACT DISC APPENDIX

Not Applicable

### BACKGROUND OF THE INVENTION

The present invention relates generally to pump control systems, and more particularly, to pump termination enclosures for multiple pumps with integral load disconnects such as are used in duplex and triplex pumping systems.

Herein, we use “low-voltage” to mean less than 50 volts. We refer to “line-voltage” as greater than 50 volts, and 120V is used to mean a specific nominal line-voltage that is lower than the line-voltage used to power the pumps. The line voltage used to power the pumps is typically 480 volt, 3-phase or 240 volt 3-phase. The 120V circuits are typically used for functions such as powering low-voltage supplies, starter coils, interposing relays, and the like.

Commonly, all components of similar systems are installed in a single enclosure or the respective pump's disconnect is installed in an enclosure such that the line and load side of the device are simultaneously exposed from a single access. Such an arrangement necessitates de-energizing the entire enclosure for service or adjustment of a single component when following safety procedures and regulations. Federal safety regulations require de-energizing enclosures containing voltages of 50 volts and higher except in specific exceptional situations. De-energizing the entire enclosure is problematic in those applications that require operation of at least one of the controlled pumps at any time, when multiple disconnects are housed in the same enclosure. Common practice is also problematic when the unit feeding power to the load disconnect enclosure is not in line of sight such that ensuring positive disconnection of the device feeding power to the enclosure being serviced is difficult to maintain.

It would therefore be desirable to design a load disconnect that allows one or more of the controlled pumps to remain in operation while components within the system are serviced within a compartment that is totally de-energized and/or a load disconnect which compartmentalizes the line and load side of the disconnecting device such that working within a completely de-energized compartment can be ensured.

### BRIEF SUMMARY OF THE INVENTION

A compartmentalized pump termination enclosure for multiple pumps with integral load disconnects consisting of multiple compartments arranged so as to allow service of each individual load side compartment without exposure to line voltages while still maintaining operation of the pumping system and being certain of maintained positive disconnection of power in regards to the compartment being serviced. The assembly includes a plurality of compartments with separate access for at minimum the line and load of the disconnecting device. Each load side compartment including a lockable handle operator that that is interlocked with its corresponding compartment door. The handle operators are either integral to the load disconnect (e.g. circuit breakers, non-trip disconnect, or the like) and directly accessible from the outside of the devices compartment, or are mechanically connected to the load disconnect via flexible cables, mechanical linkage. A key feature and distinction of this invention is that the disconnecting devices have their line and load sides segregated amongst distinct separate compartments. Thus, when the handle operator is switched to the OFF position, access is granted to the load side which in this state now contains no components (i.e. not even the disconnecting devices load side and/or its supply conductors) energized by line voltage. The assembly is constructed of an overall enclosure housing that contains within it a plurality of compartments, one or more compartments for the line side of the disconnecting device(s), and additional separate compartments as required for the load side of the disconnecting device(s).

### BRIEF DESCRIPTION OF THE SEVERAL VIEWS OF THE DRAWING

The Drawings demonstrate one solution for a preferred embodiment of the described invention.

Displayed in the drawings:

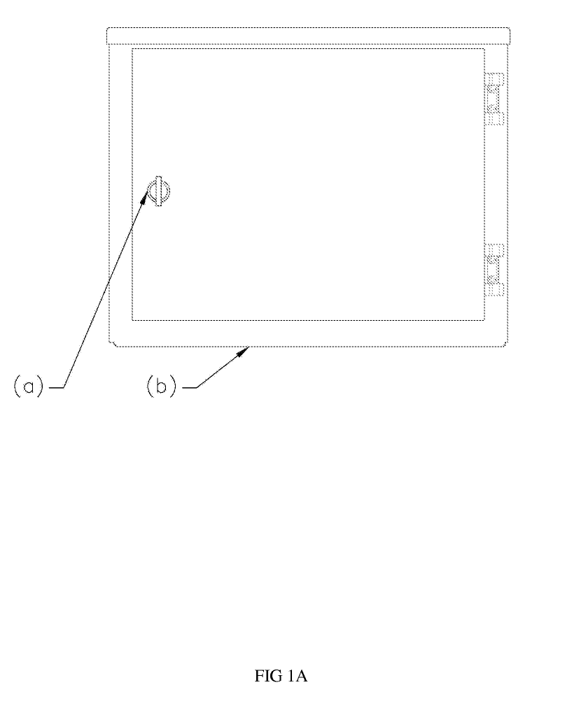

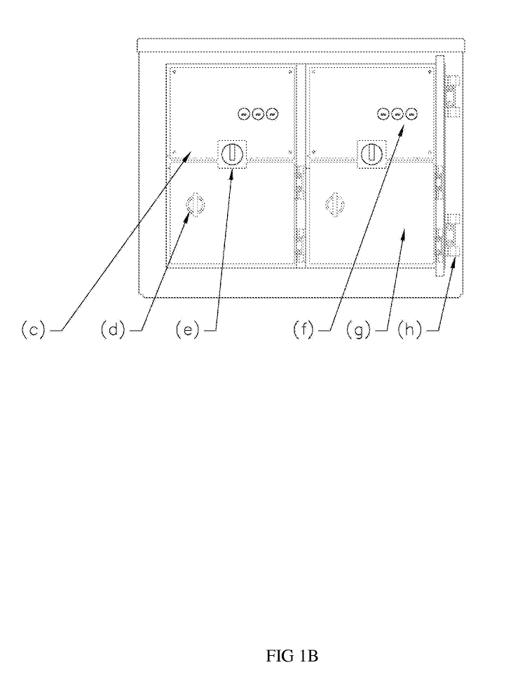

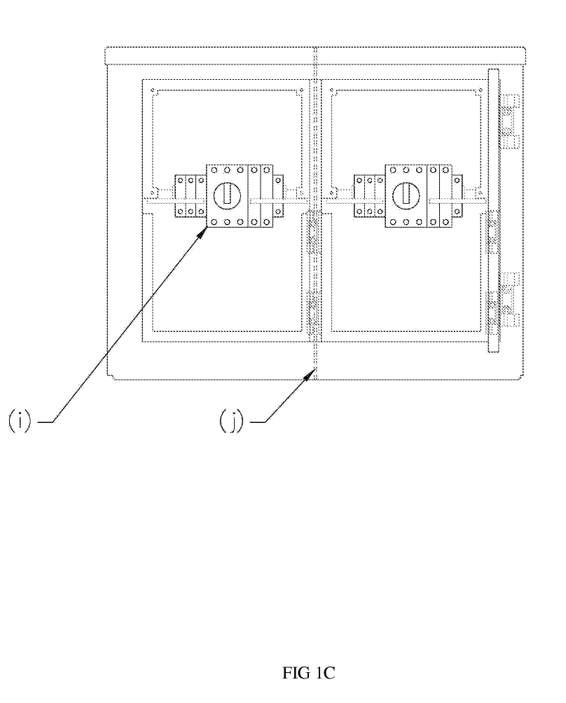

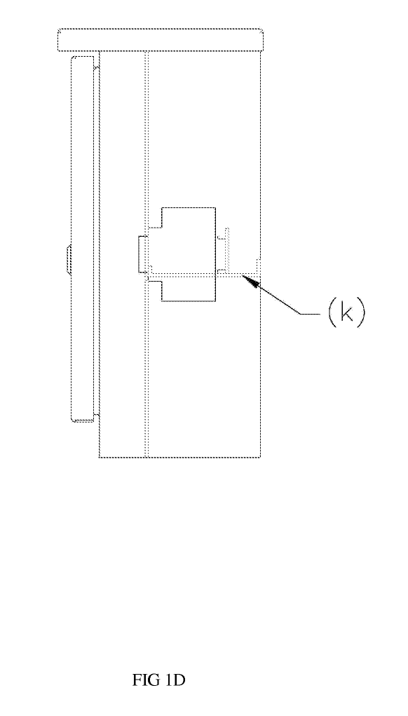

Referring to FIG. 1A, an exterior door view of the overall enclosure is shown. The doors of the overall enclosure, as well as the modular compartments, are closed in FIG. 1A.

Referring to FIG. 1B, a dead-front cover view of the modular compartments within an overall enclosure is shown. The termination compartment doors of the overall enclosure, the access plates or doors for the line side of the disconnecting devices, are closed in FIG. 1B. The exterior door for the overall enclosure is open in FIG. 1B.

Referring to FIG. 1C, an interior view of the modular compartments within an overall enclosure is shown. The termination compartment doors of the overall enclosure, the access plates or doors for the line side of the disconnecting devices, are open or removed in FIG. 1C. The exterior door for the overall enclosure is open in FIG. 1C.

Referring to FIG. 1D, a side view of the modular compartments within an overall enclosure is shown. A proposed position for the load disconnect device and a side view of the barriers within the overall enclosure are shown in FIG. 1D.

### DETAILED DESCRIPTION OF THE INVENTION

The following description makes reference to line voltage, low voltage, and the like. It is appreciated that such terms may refer to a variety of both common voltage ranges and unique voltages depending on context. However, it is appreciated that the present invention is intended for use in typical pumping system control applications and the purpose of the invention is to simplify compliance with safety regulations and procedures while keeping the pumping system in operation during such maintenance. In this context, we refer to voltages below 50 volts as “low voltage” because regulations allow access to energized control panels when only voltages below 50 exist within. We refer herein to the pump motor supply voltage as well as any other associated circuits of 50 volts or higher as “line voltage”. A typical example would consist of a system wherein the pump motors are supplied at 480 volts 3-phase, starter coils and relays and associated with the motor controllers are supplied at 120 volts 1-phase, and control system components such as programmable logic controllers and modems are supplied at 24 volts DC.

Referring to FIG. 1A, a dead-front cover view of an embodiment of the invention is shown. The overall enclosure contains within it a load disconnect as commonly used in applications such as sewage lift stations and water booster pumping stations. Components include the load disconnect and contacts for auxiliary circuits associated with the pump which is being fed by its respective disconnect.

The general appearance of the invention is similar to that of a common disconnect enclosure. However, there are important and distinct differences between the present invention and existing disconnect enclosure designs.

Disconnects typically include a circuit disconnecting device (i.e. a fused disconnect, circuit breaker, non-fused disconnect, etc.) contained within a single compartment overall enclosure. Energized conductors enter the enclosure and connect to the line side of the internal disconnecting device. The disconnect includes a handle operator that interlocks with disconnecting device (e.g. circuit breaker) that is located within the enclosure. When the handle is moved to the OFF position a door interlock allows access to the bucket. A hazard exists in that the compartment, which the door interlock has granted access to, contains parts energized at line voltage even when the handle is in the OFF position. Safety procedures and regulations do not allow working within a compartment that contains parts energized at 50 volts or higher other than specific exceptional situations.

The disconnect enclosure of the present invention is distinctly different from existing; there are two ways in which they are different that I will expound upon.

The first distinction is that in the preferred embodiment of my invention the disconnecting device has its line and load side segregated into two distinct and separate compartments, while operated by the handle operator that is part of the disconnect and interlocked with the load side compartment door. This feature eliminates the existence of energized line voltage parts within the load side compartment when the handle is switched to the OFF position. The incoming power conductors coming to the line side are in a separate compartment from those of the load side; so the incoming power conductors which may be energized are removed from the compartment which has been granted access to.

Secondly, in the preferred embodiment of my invention; where there is a multitude of load disconnects; each disconnect is compartmentalized into its own distinct line and load side compartments. By doing this, any pump within a single system can be serviced de-energized without affecting the other pumps within the same system.

It is a purpose of my invention to simplify compliance with safety regulations, thereby encouraging compliance.

Referring again to the drawings, assume it is necessary to perform maintenance to or replace one of the pumps being fed power through the load disconnect. The technician switches the respective pump's motor controller feeder breaker handle to the OFF position. The technician then goes to the load disconnects and switches the same pump's load disconnect to the OFF position. Following standard safety procedures the technician then verifies that the pump's motor leads are de-energized and locks out and tags out the handle. At this point he can perform his work on the pump (including removal and/or installation of pump cable leads terminated in the load side compartment) without concern of violating regulations as the compartment he is working in is completely de-energized of all voltage. While performing his work the pumping control system continues to operate automatically using any other pump within the system.

Another, potentially dangerous scenario is one where the motor controller for a pump is not in line of sight with its respective load disconnect or where the conductors between the motor controller and the load disconnect are in conduit, through a wall, underground or any other case where it would be difficult to visually trace the path of the conductors. A potential hazard in this case would be that the technician makes a trace error or has a lapse in memory. An example of this scenario would be that the technician goes to the motor controller of the pump that he needs to service and proceeds with locking out and tagging out this controller. After which the technician proceeds to the load disconnect of the pump and has not sufficiently traced the conductors, forgotten which pump he locked out, or had previously made the mistake of locking out the incorrect motor controller. The technician then switches the load disconnect, which he believes to be the correct one, to the OFF position. Again, following standard safety procedures the technician verifies that the pumps line and load connections are de-energized at the point of the load disconnect. The problem here is that while even if the technician takes a reading and finds the conductors to be de-energized, they may potentially not be fed by the motor controller which they had previously locked out; in this case the live motor controller may not be in a closed state and therefore would not be feeding power to the disconnect enclosure which the technician is working within at this time. After this point, the motor controller activates and switches to a closed state and feeds power to the load disconnect.

Now, that technician is illegally working within a live compartment and putting themselves at unnecessary risk.

I will here describe the components that are indicated by leaders within the several figures I have provided.

Referring to FIG. 1A, (a) is referring to a handle or latching mechanism that grants access to the dead-front covers of the interior placed, individual compartments.

Referring again to FIG. 1A, (b) is referring to the overall enclosure for a preferred embodiment of my invention.

Referring to FIG. 1B, (c) is referring to an access plate for the line side of the disconnecting device. This access plate would be preferably fastened in such a way that it would require a screw driver or other special tools to remove.

Referring again to FIG. 1B, (d) is referring to the handle operator which grants access to the load side compartment and is interlocked with the state of the disconnecting device that feeds power to its respective load side compartment.

Referring again to FIG. 1B, (e) is referring to the operating mechanism for the disconnecting device to which it is integral or interlocked with.

Referring again to FIG. 1B, (f) is referring to a voltage testing terminal that would be connected to the line side of the disconnecting device. This is an optional component in the preferred embodiment of my invention.

Referring again to FIG. 1B, (g) is referring to a hinged cover for the load side of the disconnecting device. This cover would preferably be mechanically interlocked with the disconnecting device such that when the disconnecting device is in the ON state, access would not be granted to the compartment behind this cover, and when the disconnecting device is in the OFF state, access would be granted to the compartment behind this cover.

Referring again to FIG. 1B, (h) is referring to one of several hinges that are typical within the drawing of the preferred embodiment of my invention which is provided.

Referring to FIG. 1C, (i) is referring to one of the disconnecting devices contained within the preferred embodiment of my invention. In this case, the disconnecting device is represented as having auxiliary contacts which are interlocked with the disconnecting device. The auxiliary contacts are an optional component of my invention.

Referring again to FIG. 1C, (j) is referring to a vertically aligned plate or section of material that would act as a divider between disconnect sections within the overall enclosure in the preferred embodiment of my invention.

Referring to FIG. 1D, (k) is referring to a horizontally aligned plate or section of material that would act as a divider between line and load side compartments for disconnecting devices in the preferred embodiment of my invention.

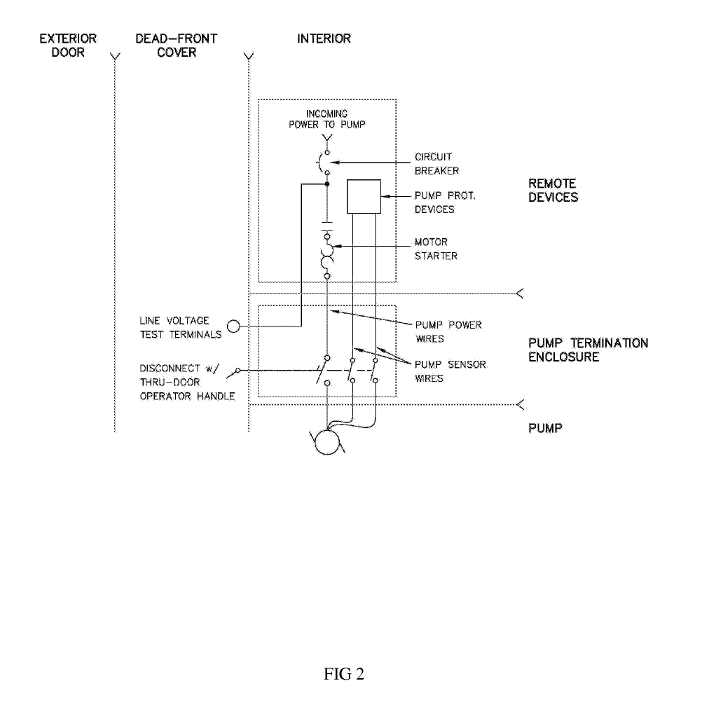

Referring to FIG. 2, this drawing is a diagrammatic representation of the preferred embodiment of my invention within a circuit of typical application. This drawing is not intended to represent every case but rather to lend an understanding as to where my invention would be located within a circuit of its typical and intended application.

To manufacture my invention:

The manufacturing entity would mount and wire as necessary the appropriate devices for each of the following aspects of pumping control within their respective compartments, while following the necessary guidelines that I have previously laid out within this document (e.g. mounting the disconnecting device in such a way that its line and load side are granted access via separate compartments.

Disconnecting Devices

Enclosure

Doors and cover plates as necessary

Other Devices, as necessary (e.g. auxiliary contacts, voltage testing terminals, conductors, mechanical linkage, and the like)

Components and methods such as; through-wall disconnect operators, interlocking handles, interlocked auxiliary contacts, doors and covers with appropriate gaskets, and the like should be used so that the integrity of isolating the compartments, from each other and a person standing in front of the system, remains in tact.

The compartments should be arranged in such a way to allow for operation and interaction of the complete system in the mode that I have described within this document.

In the preferred embodiment of my invention; all of the individual compartments would be arranged and/or mounted within an overall enclosure.

When manufacturing in volume, a complete single enclosure which includes all of the same separation by barriers and various doors and covers could be made to reduce costs and materials used for a specific configuration.

In smaller volumes use of separate enclosures installed within an overall housing is more flexible, in that various options can be pre-assembled in compartment enclosures and then assembled in different combinations for project specific requirements. For example, a triplex system could be generally the same as the duplex system shown in the figures except that three compartments would be installed in an overall enclosure of equal or greater size in respect to that which is used for two disconnect compartments as depicted in DRAWING #1.

I have herein described the preferred embodiment of the present invention in one form that would be useful for a duplex pumping control system. The specific arrangement would necessarily vary depending on the number of pumps, project specific requirements, and desired optional features. It is recognized that equivalents, alternatives, and modifications, aside from those expressly stated, are possible and within the scope of the appending claims.

What I claim as my invention is:

1. A Compartmentalized Pump Termination Enclosure for Multiple Pumps with Integral Load Disconnects assembly consisting of multiple compartments arranged so as to allow service of or access to individual compartments without exposure to line voltages while still maintaining operation of other pumps within the system.

2. The Compartmentalized Pump Termination Enclosure for Multiple Pumps with Integral Load Disconnects of claim 1 wherein disconnecting devices (e.g. circuit breakers, or non-trip disconnects) have their line and load side compartmentalized separately from one another, so as to have no line voltages present in the disconnecting devices load side compartment when disconnecting device is open.

3. The Compartmentalized Pump Termination Enclosure for Multiple Pumps with Integral Load Disconnects of claim 1 wherein each disconnect handle interlocks with its corresponding load side compartment door to prevent access to the load side compartment when the corresponding handle is in the ON position, as the load side compartment may be energized by the remote starter unit in this state.

4. The Compartmentalized Pump Termination Enclosure for Multiple Pumps with Integral Load Disconnects of claim 1 wherein each disconnect handle interlocks with its corresponding load side compartment door to grant access to the load side compartment when the handle is in the OFF position, but not to the line side compartment which contains the disconnecting device as the compartment is de-energized by the disconnecting device in this state.

5. The Compartmentalized Pump Termination Enclosure for Multiple Pumps with Integral Load Disconnects of claim 1 wherein the modular compartments are contained within an overall enclosure.
